(19) United States
(12) Patent Application Publication
(10) Pub. No.: US 2025/0248008 A1
(43) Pub. Date: Jul. 31, 2025

(54) DETECTION METHOD FOR COOLING SYSTEM AND DEVICE

(71) Applicant: Lenovo (Beijing) Limited, Beijing (CN)

(72) Inventors: Hung-Wen SUN, Beijing (CN); Chao Chun YANG, Beijing (CN); Chun-Han LIN, Beijing (CN)

(21) Appl. No.: 19/031,016

(22) Filed: Jan. 17, 2025

(30) Foreign Application Priority Data
Jan. 25, 2024 (CN) 202410107942.3

(51) Int. Cl. H05K 7/20

(52) U.S. Cl. CPC H05K 7/20836

(57) ABSTRACT

A detection method for a cooling system includes detecting first flow rate difference information of the cooling system of a server device through a flow rate detection device, and determining status information of the cooling system according to the first flow rate difference information. The first flow rate difference information indicates a difference between an inlet flow rate and an outlet flow rate of the cooling system. The status information indicates whether the cooling system has a coolant leakage.

### CROSS-REFERENCE TO RELATED APPLICATION

The present disclosure claims priority to Chinese Patent Application No. 202410107942.3, filed on Jan. 25, 2024, the entire content of which is incorporated herein by reference.

### TECHNICAL FIELD

The present disclosure is related to the cooling system technology field and, more particularly, to a detection method for a cooling system and a device.

### BACKGROUND

Servers typically have high power consumption and heat generation. To ensure that the temperature of electronic elements such as a processor and a memory in the servers remains within an appropriate range, a cooling system is required to cool the server device.

To achieve good cooling effect, a server generally employs a liquid cooling system. The liquid cooling system includes a large number of pipelines for circulating the coolant. The heat generated by the electronic elements in the server during operation can be absorbed by the coolant in the pipelines to reduce the temperature.

However, the liquid cooling system has a coolant leakage risk due to a damaged pipeline wall. Thus, how to detect whether the cooling system has coolant leakage needs to be solved in the related field.

### SUMMARY

An aspect of the present disclosure provides a detection method for a cooling system. The method includes detecting first flow rate difference information of the cooling system of a server device through a flow rate detection device, and determining status information of the cooling system according to the first flow rate difference information. The first flow rate difference information indicates a difference between an inlet flow rate and an outlet flow rate of the cooling system. The status information indicates whether the cooling system has a coolant leakage.

An aspect of the present disclosure provides a detection device for a cooling system, including a first sensor, a second sensor, and a controller. The first sensor is arranged at an inlet of the cooling system and configured to obtain flow rate pulse data for a liquid of the cooling system based on a Hall sensor. The second sensor is arranged at an outlet of the cooling system and configured to obtain flow rate pulse data for the liquid of the cooling system based on a Hall sensor. The controller is configured to detect first flow rate difference information of the cooling system of a server device through the first sensor and the second sensor, and determine status information of the cooling system according to the first flow rate difference information. The status information indicates whether the cooling system has a coolant leakage. The first flow rate difference information indicates a difference between an inlet flow rate and an outlet flow rate of the cooling system.

### BRIEF DESCRIPTION OF THE DRAWINGS

FIG. 1 illustrates a schematic flowchart of a detection method for a cooling system according to some embodiments of the present disclosure.

FIG. 2 illustrates a schematic structural diagram of a first sensor according to some embodiments of the present disclosure.

FIG. 3 illustrates a schematic diagram showing pulse data of a first sensor and a second sensor according to some embodiments of the present disclosure.

FIG. 4 illustrates a schematic diagram showing installation positions of a first sensor and a second sensor according to some embodiments of the present disclosure.

FIG. 5 illustrates a schematic diagram of other installation positions of a first sensor and a second sensor according to some embodiments of the present disclosure.

FIG. 6 illustrates a schematic structural diagram of a detection device for a cooling system according to some embodiments of the present disclosure.

### DETAILED DESCRIPTION OF THE EMBODIMENTS

The technical solutions of embodiments of the present disclosure are described in detail below in conjunction with the accompanying drawings of embodiments of the present disclosure. Apparently, the described embodiments are merely some embodiments of the present disclosure, not all embodiments. Based on embodiments of the present disclosure, all other embodiments obtained by those skilled in the art without creative efforts are within the scope of the present disclosure.

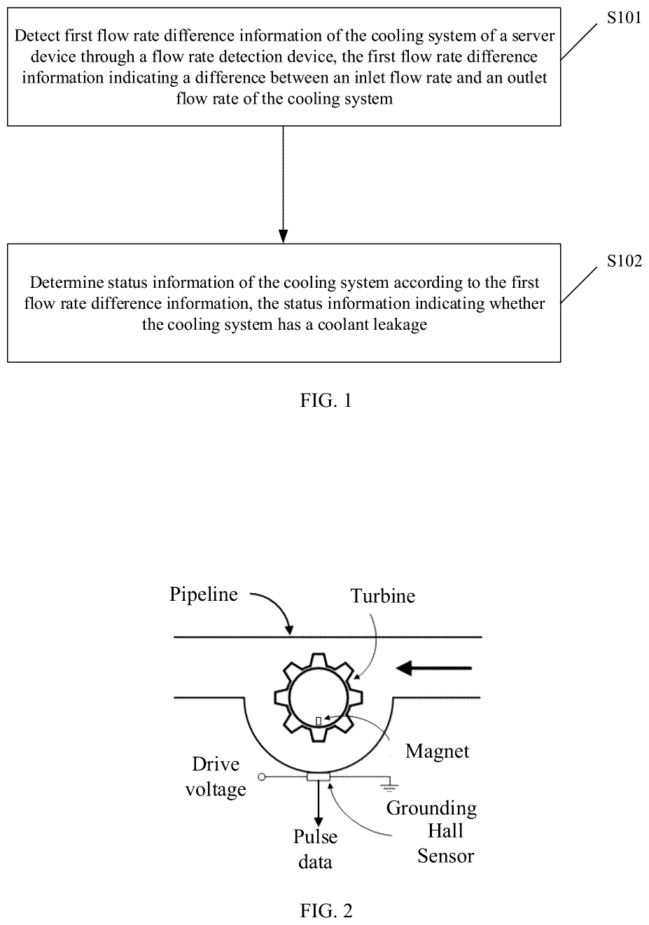

Embodiments of the present disclosure provide a detection method of a cooling system. FIG. 1 illustrates a schematic flowchart of a detection method for a cooling system according to some embodiments of the present disclosure. The method includes the following steps.

At S101, the first flow rate difference information of a liquid cooling system of a server device is detected by a flow rate detection device. The first flow rate difference information is used to represent a difference between an inlet flow rate and an outlet flow rate.

In the detection method of embodiments of the present disclosure, an execution body can be a controller that is communicatively connected to the flow rate detection device. The controller can be integrated into a motherboard of the server device, be plugged into a device interface integrated at the motherboard of the server device, or be an original processor of the motherboard of the server device.

In the liquid cooling system of embodiments of the present disclosure, the coolant can be cooling water or other liquids having a cooling effect, which is not limited.

In some embodiments, the flow rate detection device can include a first sensor and a second sensor. The first sensor can be arranged at an inlet of the cooling system of the server device. The second sensor can be arranged at an outlet of the cooling system. Accordingly, the method for detecting the first flow rate difference information of the cooling system through the flow rate detection device can include obtaining a first flow rate signal of the first sensor and a second flow rate signal of the second sensor, and determining the first flow rate difference information of the cooling system according to frequencies of the first flow rate signal and the second flow rate signal.

The first sensor and the second sensor can be any type of sensor capable of detecting a liquid flow rate. The types of the first sensor and the second sensor are not limited in the present disclosure.

For example, the first sensor and the second sensor can be flowmeters based on Hall sensors. The first flow rate signal can be flow rate pulse data detected by the first sensor at the inlet of the cooling system. The second flow rate signal can be flow rate pulse data detected by the second sensor at the outlet of the cooling system.

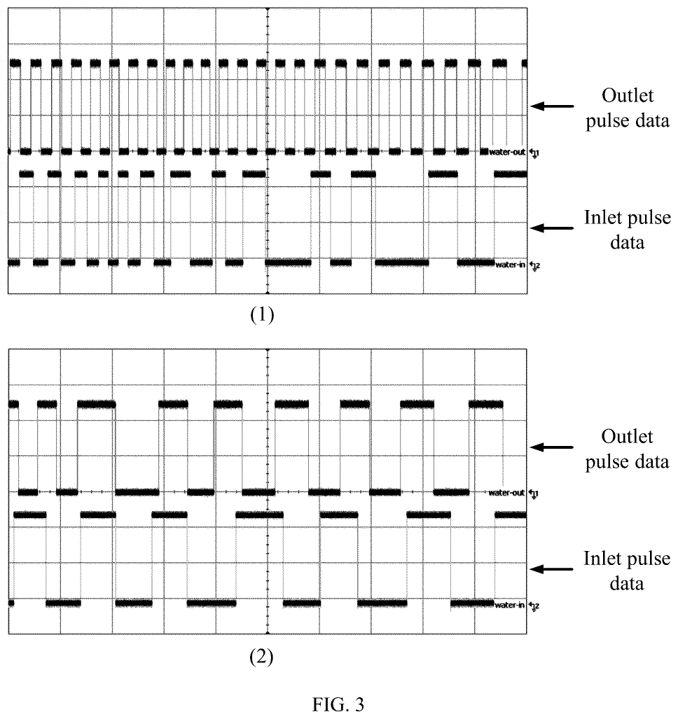

When the first sensor and the second sensor are the flowmeters based on Hall sensors, the flowmeters have a structure as shown in FIG. 2. The pulse data detected by the first sensor and the pulse data detected by the second sensor are shown as (1) and (2) in FIG. 3.

As shown in FIG. 2, the first sensor includes a turbine, a magnet arranged at the turbine, and a Hall sensor arranged on a side of the turbine. When liquid flows through a pipeline, the liquid can drive the turbine to rotate, and the magnet can rotate with the turbine to cause the magnetic field strength detected by the Hall sensor to change with the rotation of the magnet. The Hall sensor can output pulse data reflecting a magnetic field change frequency. When the flow rate is higher, the turbine can rotate faster, and the frequency of the pulse data can be higher. When the flow rate is lower, the frequency of the pulse data can be lower. Thus, the flow rate of the liquid passing through the flowmeter can be reflected by the frequency of the pulse data.

Determining the first flow rate difference information according to the frequencies of the first flow rate signal and the second flow rate signal can include the following method.

The first sensor can determine the flow rate corresponding to the frequency of the first flow rate signal, i.e., the inlet flow rate of the cooling system, for example, A meters per second. The second sensor can determine the flow rate corresponding to the frequency of the second flow rate signal, i.e., the outlet flow rate of the cooling system, for example, B meters per second. Then, the controller can calculate the difference between the inlet flow rate and the outlet flow rate to obtain the first flow rate difference information, for example, (A-B) meters per second.

In another method, the frequency of the first flow rate signal and the frequency of the second flow rate signal can represent the inlet flow rate and the outlet flow rate of the cooling system, respectively. The difference in the frequencies of the two signals can represent the difference between the inlet flow rate and the outlet flow rate. Thus, the controller can also calculate the frequency difference between the frequency of the first flow rate signal and the frequency of the second flow rate signal. The frequency difference can be determined as the first flow rate difference information.

At S102, the status information of the cooling system is determined according to the first flow rate difference information. The status information indicates whether a coolant leakage occurs in the cooling system.

The method of determining the status information of the cooling system according to the first flow rate difference information can include at least one of, if the first flow rate difference information is less than a first threshold, determining the status information of the cooling system as first status information, the first status information indicating that no coolant leakage occurs in the cooling system, if the first flow rate difference information is greater than or equal to the first threshold, determining the status information of the cooling system as second status information, the second status information indicating that a coolant leakage occurs in the cooling system, or if the first flow rate difference information is greater than or equal to the first threshold and lasts for a predetermined time length, determining the status information of the cooling system as second status information.

The advantage of determining the status information in the third method above is that when the first flow rate difference information is detected by the sensor, the sensor may have an occasional error within a short period. For example, only the first flow rate difference information detected within 0.5 seconds can exceed the first threshold. Then, the subsequently detected first flow rate difference information can be smaller than the first threshold. Then, the first flow rate difference information detected within 0.5 seconds can be the error. Determining the status information in the third method can prevent the error from being determined as the coolant leakage. Thus, the false alarm rate of the detection method of embodiments of the present disclosure can be reduced.

In some embodiments, the first threshold can be a pre-arranged fixed threshold or a threshold dynamically changing with the inlet flow rate of the cooling system.

For example, when the first flow rate difference information is the difference between the inlet flow rate and the outlet flow rate, the first threshold can be set as a certain percentage of the inlet flow rate, e.g., 5% of the inlet flow rate.

For another example, when the first flow rate difference information is the frequency difference between the frequency of the first flow rate signal and the frequency of the second flow rate signal, the first threshold can be set as a certain percentage of the frequency of the first flow rate signal, e.g., 5% of the frequency of the first flow rate signal.

The predetermined time length can be set based on actual conditions, such as 10 seconds, 30 minutes, 20 minutes, etc., which is not limited.

When the cooling system has a coolant leakage, the leaking situation can be different according to the different damages in the pipelines.

For example, when the damage is severe, and the pipeline has visible cracks or holes, the cooling system can continuously have a coolant leakage. Then, the first flow rate difference information can always be greater than or equal to the first threshold within the predetermined time length.

When the damage is minor, and the pipeline has tiny and invisible cracks, the cooling system can only have a coolant leakage when the inlet flow rate is high, and the pressure of the liquid acting on the pipeline is high. When the inlet flow rate is low, the coolant leakage may not happen, or the leak is light and cannot be detected. In some periods, the first flow rate difference information can be greater than or equal to the first threshold in a part of time, while the first flow rate difference information may be smaller than the first threshold.

Considering the above situation, the predetermined time length can include a plurality of different kinds of predetermined time lengths. The controller can use different detection strategies to determine the second status information for different predetermined time lengths.

For example, the predetermined time length can include a first predetermined time length and a second predetermined time length. The controller can determine the second status information according to at least one of the following detection strategies.

In detection strategy one, if the first flow rate difference information is greater than or equal to the first threshold, which lasts for the first predetermined time length, the status information of the cooling system can be determined as the second status information. The second status information can indicate that the cooling system has a coolant leakage.

In detection strategy two, if a number of the first flow rate difference information detected within the second predetermined time length being greater than or equal to the first threshold achieves the first count threshold, the status information of the cooling system can be determined as the second status information. The second predetermined time length can be greater than the first predetermined time length.

In detection strategy one, the first flow rate difference information being greater than or equal to the first threshold, which lasts for the first predetermined time length can indicate that, in the first predetermined time length, the first flow rate difference information each moment obtained by the controller can be greater than or equal to the first threshold. For example, the first predetermined time length can be 10 seconds. If the first flow rate difference information each time obtained by the controller is greater than or equal to the first threshold, the status information can be determined as the second status information.

In detection strategy two, the count of the first flow rate difference information being detected to be greater than or equal to the first threshold can indicate that the times of the first flow rate difference information is greater than or equal to the first threshold, which lasts the time length threshold. The time length threshold can be 1 second, 2 seconds, or other value, and can be normally smaller than the first predetermined time length.

For example, if the controller finds that the first flow rate difference information obtained within 2 consecutive seconds is greater than or equal to the first threshold, and after 2 seconds, the first flow rate difference information is less than the first threshold, the controller can record that the first flow rate difference information being greater than or equal to the first threshold is detected for one time.

The second predetermined time length and the first count threshold can be determined according to the actual conditions. For example, the second predetermined time length can be 30 minutes, and the first count threshold can be 5 times.

The advantages of determining the second status information in the above method can include that different degrees of coolant leakages of the cooling system are detected through different detection strategies to improve the accuracy probability of the detection method of embodiments of the present disclosure to avoid missing leak detections.

In embodiments of the present disclosure, the cooling system can include a pipeline arranged on the motherboard. The first sensor can be arranged at one end of the pipeline inputting the coolant into the cooling system. The second sensor can be arranged at one end of the pipeline discharging coolant from the cooling system.

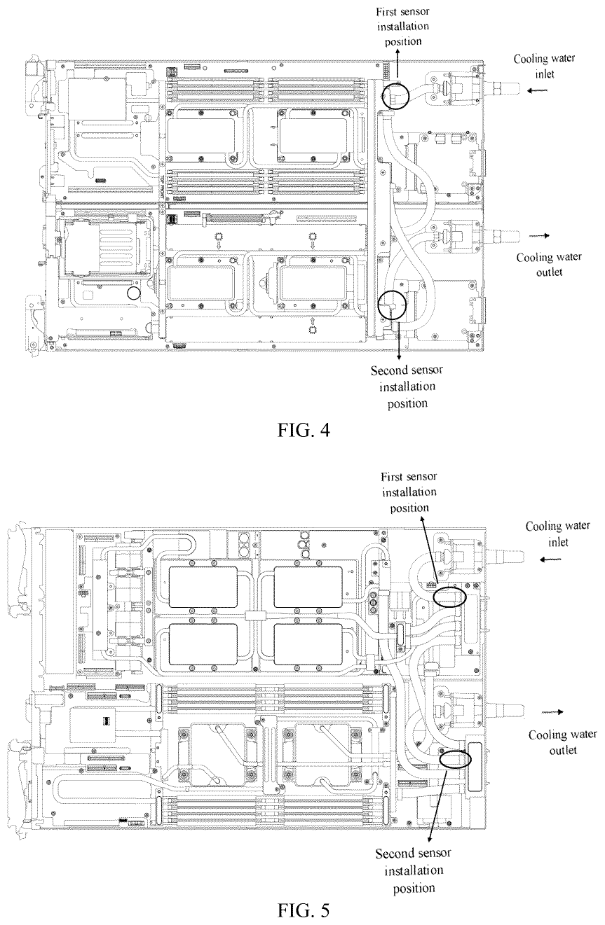

For example, when the motherboard of the server device is the motherboard shown in FIG. 4, the first sensor and the second sensor are arranged at the positions shown in FIG. 4. When the motherboard of the server device is the motherboard shown in FIG. 5, the first sensor and the second sensor are arranged at the positions shown in FIG. 5.

As shown in FIG. 1, the detection method of the cooling system has the beneficial effect as follows. Whether the cooling system has a coolant leakage can be detected according to the first flow rate difference information of the liquid cooling system of the server device. Thus, a response measure can be taken in time when the coolant leakages to protect the server device and prevent the server device from being damaged due to the coolant leakage.

Furthermore, in the detection method of embodiments of the present disclosure, only two flow rate sensors can be arranged at the inlet and the outlet of the cooling system to detect the coolant leakage. The sensor can have a small volume and be easy to install. Thus, the sensor can be quickly installed or removed according to the needs of the user to meet the application requirements of different application scenarios.

In some embodiments, after determining the status information as the second status information, the controller can perform at least one of response measure 1 of when determining the status information of the cooling system as the second status information, powering off the server device and response measure 2 of when determining the status information of the cooling system as the second status information, issuing a coolant leakage warning to the maintenance personnel of the server device.

In response measure 1, the controller can be communicatively connected to a power module of the server device. After determining the status information as the second status information, the controller can send a power-off signal to the power module to control the power module to power off to control the server device to power off.

In response measure 2, the coolant leakage warning can be issued in any manner, including controlling a coolant leakage indicator to emit light in a specific color (e.g., red) and/or a specific mode (e.g., flashing), controlling a speaker to emit specific warning audio or speech, controlling a display module to show the coolant leakage warning, controlling a terminal device used by the maintenance personnel (e.g., a desktop terminal or a handheld terminal) to display the coolant leakage warning, and controlling a wearable device worn by the maintenance personnel to vibrate in a specific vibration mode.

The benefit of taking the above response measures includes, on one aspect, powering off the server device in time when the coolant leakages to avoid the server device continuing to operate on power with the coolant leakage to damage electronic elements or cause fire, and on another aspect, prompting the maintenance personnel to process and maintain in time by issuing the coolant leakage warning.

The controller can also first issue the coolant leakage warning according to response measure 2 and determine whether the maintenance personnel of the server device has processed the coolant leakage warning. If after a certain time, e.g., 1 minute, the coolant leakage warning is determined to be not processed by the server device, the server device can be powered off according to response measure 1.

Determining whether the maintenance personnel of the server device has processed the coolant leakage warning can include, if the server device is not powered off, determining that the coolant leakage warning is not processed, and if the server device is powered off, determining that the coolant leakage warning is processed.

Determining whether the maintenance personnel of the server device processes the coolant leakage warning can also include obtaining a processing instruction of the maintenance personnel through an input assembly, the processing instruction indicating that the maintenance personnel has acknowledged the coolant leakage warning and taken processing measures, if the processing instruction is received, determining that the coolant leakage warning has been processed, and if the processing instruction is not received, determining that the coolant leakage warning has not been processed.

Of course, both of the above methods can be used simultaneously to determine whether the coolant leakage warning has been processed.

Furthermore, which response measures to take can be determined according to the severity of the coolant leakage.

For example, when the controller determines the second status information according to detection strategy 2, the coolant leakage can be determined. However, the leak severity is minor with a small leakage volume. Then, response measure 2 can be performed, or response measure 2 can be performed first followed by response measure 1. When the controller determines the second status information according to detection strategy 1, the coolant leakage can be determined with a relatively high leak severity. Then, the server device can be directly powered off according to response measure 1.

In some embodiments, when determining the status information of the cooling system according to the first flow rate difference information, the controller can also set a second threshold greater than the first threshold. When the first flow rate difference information is greater than the second threshold, the pipeline of the cooling system can be considered to be seriously damaged. Then, the status information of the cooling system can be directly determined as the second status information without waiting for the predetermined time length. That is, the controller can determine the second status information according to the following detection strategy 3.

In detection strategy 3, if the first flow rate difference information is detected to be greater than or equal to the second threshold, the status information of the cooling system can be determined as the second status information. The second threshold can be greater than the first threshold.

Similar to the first threshold, the second threshold can be a fixed value or a floating value set as a certain proportion of the inlet flow rate or the frequency of the first flow rate signal. For example, the second threshold can be 10% of the inlet flow rate or 10% of the frequency of the first flow rate signal.

The beneficial effect of embodiments of the present disclosure can include that when a large amount of coolant is leaked, the corresponding response measures can be taken in time without waiting for the predetermined time length to avoid electronic element errors or other serious problems due to delayed responses.

In the detection method of embodiments of the present disclosure, a pre-warning can be provided based on the first flow rate difference information to prompt the relevant maintenance personnel to perform timely repair before the cooling system has the coolant leakage. The pre-warning can include, if the count of detecting that the first flow rate difference information is greater than or equal to the first threshold within the third predetermined time length achieves the second count threshold, outputting the first status prompt information. The first status prompt information can indicate that the cooling system has a coolant leakage risk. The second count threshold can be smaller than the first count threshold. The third predetermined time length can be greater than the first predetermined time length and smaller than the second predetermined time length.

The content of the first status prompt information is not limited, as long as the content can indicate the coolant leakage risk to the relevant personnel. For example, the first status prompt information can include “The water-cooling system of the server may have a leakage, please inspect and repair promptly.”

For example, the second count threshold can be set to 1 or 2, and the third predetermined time length can be set to 60 seconds.

The output method of the first status prompt information can refer to the output method for the coolant leakage warning, which is not repeated here.

In some embodiments, several third sensors can also be arranged in the cooling system. A third sensor can be a flowmeter based on Hall sensors or other sensors capable of detecting the liquid flow rate. The third sensors can be arranged at inlet ends and outlet ends of a plurality of pipelines of the cooling system. Thus, when the controller outputs the first status prompt information, the controller can be configured to obtain a second flow rate difference of different pipelines in the cooling system, determine a target pipeline from the different pipelines of the cooling system according to the second flow rate difference, and outputting the second status prompt information corresponding to the target pipeline. The second status information can indicate that the corresponding target pipeline has a coolant leakage risk.

Based on the above, for the pipelines of the cooling system provided with the third flow sensors at the inlet ends and the outlet ends, the controller can obtain the second flow rate difference according to the flow rate signals of the third flow sensors at the inlet ends and the flow rate signals of the third flow sensors at the outlet ends. For the method for obtaining the second flow rate difference, reference can be made to the method for obtaining the first flow rate difference information, which is not repeated here.

The method for determining the target pipeline according to the second flow rate difference can include, for each pipeline provided with the third flow sensor, determining whether the second flow rate difference of the pipeline is greater than the third threshold corresponding to the pipeline, if the second flow rate difference is greater than the third threshold, determining that the pipeline is the target pipeline, and if the second flow rate difference is smaller than the third threshold, determining that the pipeline is not the target pipeline.

The target pipeline can be one or more pipelines having the coolant leakage risk of the plurality of pipelines of the cooling system or one or more pipelines with the highest coolant leakage risk of the plurality of pipelines.

Different pipelines can correspond to the same third threshold or different third thresholds. When the different pipelines correspond to different third thresholds, for any one pipeline provided with the third flow sensor, the third threshold of the pipeline can be set to 5% (or other proportions) of the flow rate at the inlet end of the pipeline or 5% (or other proportions) of the frequency of the flow rate signal at the inlet end of the pipeline.

The second status prompt information can be output together with the first status prompt information or separately after the first status prompt information is output. For the method for outputting the second status prompt information, reference can be made to the method for outputting the coolant leakage warning, which is not repeated here.

The content of the second status prompt information is not limited. For example, the second status prompt information can include “The cooling pipeline of processor No. 1 of the server motherboard may have a leakage, please inspect and repair promptly.”

The beneficial effect of embodiments of the present disclosure can include, when the cooling system is detected to have a coolant leakage risk, indicating one or more pipelines with relatively high leakage risk through the second status prompt information to facilitate the maintenance personnel to quickly inspect and repair the pipelines with high risk to improve the maintenance efficiency of the server device.

In some embodiments, the detection method of embodiments of the present disclosure can further include, when at least one of the outlet flow rate and the inlet flow rate of the cooling system is smaller than a fourth threshold, outputting third status prompt information. The third status prompt information can indicate that the cooling system has a blockage risk.

The fourth threshold can be a fixed value, e.g., a minimum flow rate of the liquid entering the cooling system when the cooling system operates normally. If the outlet flow rate and/or the inlet flow rate of the cooling system is smaller than the fourth threshold, the pipeline of the current cooling system can have blockage to cause the flow rate of the liquid to be reduced.

The fourth threshold can also be a floating value related to the actual operation condition of the cooling system.

For example, the higher the input power of the server equipment, the greater the heat it generates. Accordingly, the device delivering coolant to the cooling system pipelines will typically provide coolant at a higher flow rate to maintain the temperature stability of the server equipment. Therefore, if the server equipment's input power is high but the inlet and/or outlet flow rate of the cooling system does not match this input power, it can be considered that there may be a blockage in the cooling system pipeline, causing the device delivering the coolant to be unable to deliver the coolant at the flow rate corresponding to the input power.

Thus, the correspondence between the input power of the server device and the expected flow rate can be pre-determined. When performing the above steps, the current input power of the server device can first be obtained from the power assembly of the server device. Based on the correspondence between the input power and the expected flow rate, the expected flow rate corresponding to the current input power can be obtained. The obtained expected flow rate can be determined as the fourth threshold.

The content of the third status prompt information is not limited. For example, the third status prompt information can include “The cooling system has a blockage risk, please inspect and repair promptly.”

For the method for outputting the third status prompt information, reference can be made to the method for outputting the coolant leakage warning, which is not repeated here.

The beneficial effect of embodiments of the present disclosure can include detecting whether the cooling system has the blockage according to the input flow rate and the output flow rate of the cooling system.”

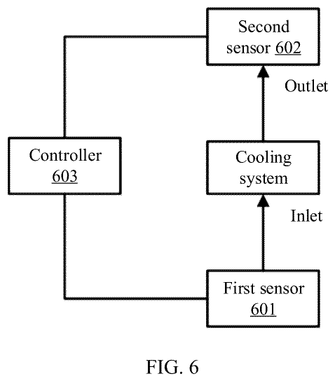

Embodiments of the present disclosure further provide a detection device for a cooling system. FIG. 6 illustrates a schematic structural diagram of the detection device according to embodiments of the present disclosure. The detection device includes a first sensor 601 arranged at the inlet of the cooling system, a second sensor 602 arranged at the outlet of the cooling system, and a controller 603.

The first sensor 601 and the second sensor 602 can be configured to obtain the flow rate pulse data of the fluid in the cooling system based on the Hall sensors and obtain the flow rate of the fluid based on the pulse data.

The controller 603 can be configured to detect the first flow rate difference information of the cooling system of the server device through the first sensor and the second sensor and determine the status information of the cooling system according to the first flow rate difference information. The first flow rate difference information can indicate the difference between the inlet flow rate and the outlet flow rate of the cooling system. The status information can indicate whether the cooling system has a coolant leakage.

In some embodiments, when determining the status information of the cooling system according to the first flow rate difference information, the controller 603 can be configured to perform at least one of, if the first flow rate difference information is smaller than the first threshold, determining the status information of the cooling system as the first status information, the first status information indicating that the cooling system does not have the coolant leakage, or if the first flow rate difference information is greater than or equal to the first threshold for the predetermined time length, determining the status information of the cooling system as the second status information, the second status information indicating that the cooling system has the coolant leakage.

In some embodiments, when determining the status information of the cooling system as the second status information if the first flow rate difference information is greater than or equal to the first threshold for the predetermined time length, the controller 603 can be configured to perform at least one of, if the first flow rate difference information is greater than or equal to the first threshold for the first predetermined time length, determining the status information of the cooling system as the second status information, the second status information indicating that the cooling system has the coolant leakage, or if the count of the first flow rate difference information is greater than or equal to the first threshold detected within the second predetermined time length achieves the first count threshold, determining the status information of the cooling system as the second status information, the second predetermined time length being greater than the first predetermined time length.

In some embodiments, the controller 603 can be further configured to, when determining the status information of the cooling system as the second status information, control the server device to power off or issue a coolant leakage warning to the maintenance personnel of the server device.

In some embodiments, when determining the status information of the cooling system according to the first flow rate difference information, the controller 603 can be further configured to, if the first flow rate difference information is detected to be greater than or equal to the second threshold, determine the status information of the cooling system as the second status information, the second threshold being greater than the first threshold.

In some embodiments, the controller 603 can be further configured to, if the count of the first flow rate difference information being greater than or equal to the first threshold detected within the third predetermined time length achieves the second count threshold, output the first status prompt information. The first status prompt information can indicate that the cooling system has the coolant leakage risk. The second count threshold can be smaller than the first count threshold. The third predetermined time length can be greater than the first predetermined time length and smaller than the second predetermined time length.

In some embodiments, the controller 603 can be further configured to obtain the second flow rate difference between different pipelines in the cooling system, determine the target pipeline from the different pipelines of the cooling system according to the second flow rate difference, and output the second status prompt information corresponding to the target pipeline. The second status prompt information can indicate that the corresponding target pipeline has a coolant leakage risk.

In some embodiments, when detecting the first flow rate difference information of the cooling system of the server device, the controller 603 can be configured to obtain the first flow rate signal of the first sensor and the second flow rate signal of the second sensor and determine the first flow rate difference information of the cooling system according to the frequency of the first flow rate signal and the frequency of the second flow rate signal. The first sensor can be arranged at the inlet of the cooling system of the server device. The second sensor can be arranged at the outlet of the cooling system.

In some embodiments, the controller 603 can be further configured to output the third status prompt information when at least one of the outlet flow rate or the inlet flow rate of the cooling system is smaller than the fourth threshold. The third status prompt information can indicate that the cooling system has a blockage risk.

In the detection device of the cooling system of embodiments of the present disclosure, for the specific operation principle and beneficial effect, reference can be made to the related steps and beneficial effects of the detection method of the cooling system of embodiments of the present disclosure, which is not repeated here.

Each embodiment in the specification is described in a progressive manner. Each embodiment focuses on the difference from other embodiments. The similar or identical parts between embodiments can be referred to each other.

To facilitate description, when the system or apparatus is described, the system or apparatus can be functionally divided into modules or units, which can be described separately. Of course, the functions of the units can be implemented in the same one or more pieces of software and/or hardware when the present disclosure is implemented.

Based on the above description of embodiments of the present disclosure, those skilled in the art can understand that the present disclosure can be implemented by software plus necessary and general hardware platforms. Based on this understanding, the essence or the part contributing to the related technology of the technical solution of the present disclosure can be implemented by a software product. The computer software product can be stored in a storage medium, e.g., ROM/RAM, magnetic disks, optical disks, etc., and include several instructions to enable a computer device (e.g., a personal computer, server, network device, etc.) to execute the methods described in various embodiments or certain parts of embodiments of the present disclosure.

Finally, relational terms such as “first,” “second,” “third,” and “fourth” are only used to distinguish one entity or operation from another entity or operation and do not necessarily require or imply any such actual relationship or order between these entities or operations. Moreover, the terms “include,” “comprise,” or any variations thereof are intended to cover non-exclusive inclusions, such that a process, method, item, or device that includes a series of elements not only includes those elements but also includes other elements not expressly listed or elements inherent to such process, method, item, or device. When there is no more limitations, an element defined by a phrase “include a . . . ” does not exclude the presence of additional and identical elements in the process, method, item, or device that includes the element.

The above are merely some embodiments of the present disclosure. For those of ordinary skill in the art, several improvements and modifications can be made without departing from the principles of the present disclosure. These improvements and modifications should also be within the scope of the present disclosure.

What is claimed is:

1. A detection method for a cooling system comprising:
detecting first flow rate difference information of the cooling system of a server device through a flow rate detection device, the first flow rate difference information indicating a difference between an inlet flow rate and an outlet flow rate of the cooling system; and
determining status information of the cooling system according to the first flow rate difference information, the status information indicating whether the cooling system has a coolant leakage.

2. The method of claim 1, wherein determining the status information of the cooling system according to the first flow rate difference information includes at least one of:
in response to the first flow rate difference information being smaller than a first threshold, determining the status information of the cooling system as first status information, the first status information indicating that the cooling system has no coolant leakage; or
in response to the first flow rate difference information being greater than or equal to the first threshold for a predetermined time length, determining the status information of the cooling system as second status information, the second status information indicating that the cooling system has the coolant leakage.

3. The method of claim 2, wherein in response to the first flow rate difference information being greater than or equal to the first threshold for the predetermined time length, determining the status information of the cooling system as the second status information includes at least one of:
in response to the first flow rate difference information being greater than or equal to the first threshold for a first predetermined time length, determining the status information of the cooling system as the second status information, the second status information indicating that the cooling system has the coolant leakage; or
in response to a count of the first flow rate difference information being greater than or equal to the first threshold detected within a second predetermined time length achieving a first count threshold, determining the status information of the cooling system as the second status information, the second predetermined time length being greater than the first predetermined time length.

4. The method of claim 3, further comprising, in response to determining the status information of the cooling system as the second status information:
controlling the server device to power off; or
issuing a coolant leakage warning to the maintenance personnel of the server device.

5. The method of claim 2, wherein determining the status information of the cooling system according to the first flow rate difference information further includes:
in response to detecting that the first flow rate difference information is greater than or equal to a second threshold, determining the status information of the cooling system as the second status information, the second threshold being greater than the first threshold.

6. The method of claim 1, further comprising, in response to a count of the first flow rate difference information being greater than or equal to the first threshold detected within a third predetermined time length achieving a second count threshold, outputting first status prompt information, wherein:
the first status prompt information indicates that the cooling system has a coolant leakage risk;
the second count threshold is smaller than the first count threshold; and
the third predetermined time length is greater than the first predetermined time length and smaller than the second predetermined time length.

7. The method of claim 6, further comprising:
obtaining a second flow rate difference of different pipelines of the cooling system;
determining a target pipeline from the different pipelines of the cooling system according to the second flow rate difference; and
outputting second status prompt information corresponding to the target pipeline, the second status prompt information indicating that the corresponding target pipeline has the coolant leakage risk.

8. The method of claim 1, wherein detecting the first flow rate difference information of the cooling system of the server device includes:
obtaining a first flow rate signal of a first sensor and a second flow rate signal of a second sensor, the first sensor being arranged at an inlet of the cooling system of the server device, and the second sensor being arranged at an outlet of the cooling system; and
determining the first flow rate difference information of the cooling system according to a frequency of the first flow rate signal and a frequency of the second flow rate signal.

9. The method of claim 1, further comprising:
in response to at least one of the outlet flow rate or the inlet flow rate of the cooling system being smaller than a fourth threshold, outputting the third status prompt information, the third status prompt information indicating that the cooling system has a blockage risk.

10. A detection device for a cooling system comprising:
a first sensor arranged at an inlet of the cooling system and configured to obtain flow rate pulse data for a liquid of the cooling system based on a Hall sensor;
a second sensor arranged at an outlet of the cooling system and configured to obtain flow rate pulse data for the liquid of the cooling system based on a Hall sensor; and
a controller configured to:
detect first flow rate difference information of the cooling system of a server device through the first sensor and the second sensor, the first flow rate difference information indicating a difference between an inlet flow rate and an outlet flow rate of the cooling system; and
determine status information of the cooling system according to the first flow rate difference information, the status information indicating whether the cooling system has a coolant leakage.

11. The device of claim 10, wherein the controller is further configured to perform at least one of:
in response to the first flow rate difference information being smaller than a first threshold, determining the status information of the cooling system as first status information, the first status information indicating that the cooling system has no coolant leakage; or
in response to the first flow rate difference information being greater than or equal to the first threshold for a predetermined time length, determining the status information of the cooling system as second status information, the second status information indicating that the cooling system has the coolant leakage.

12. The device of claim 11, wherein the controller is further configured to perform at least one of:
in response to the first flow rate difference information being greater than or equal to the first threshold for a first predetermined time length, determining the status information of the cooling system as the second status information, the second status information indicating that the cooling system has the coolant leakage; or
in response to a count of the first flow rate difference information being greater than or equal to the first threshold detected within a second predetermined time length achieving a first count threshold, determining the status information of the cooling system as the second status information, the second predetermined time length being greater than the first predetermined time length.

13. The device of claim 12, wherein the controller is further configured to, in response to determining the status information of the cooling system as the second status information:
control the server device to power off; or
issue a coolant leakage warning to the maintenance personnel of the server device.

14. The device of claim 11, wherein the controller is further configured to:
in response to detecting that the first flow rate difference information is greater than or equal to a second threshold, determine the status information of the cooling system as the second status information, the second threshold being greater than the first threshold.

15. The device of claim 10, wherein:
the controller is further configured to, in response to a count of the first flow rate difference information being greater than or equal to the first threshold detected within a third predetermined time length achieving a second count threshold, output first status prompt information;
the first status prompt information indicates that the cooling system has a coolant leakage risk;
the second count threshold is smaller than the first count threshold; and
the third predetermined time length is greater than the first predetermined time length and smaller than the second predetermined time length.

16. The device of claim 15, wherein the controller is further configured to:
obtain a second flow rate difference of different pipelines of the cooling system;
determine a target pipeline from the different pipelines of the cooling system according to the second flow rate difference; and
output second status prompt information corresponding to the target pipeline, the second status prompt information indicating that the corresponding target pipeline has the coolant leakage risk.

17. The device of claim 10, wherein the controller is further configured to:
obtain a first flow rate signal of a first sensor and a second flow rate signal of a second sensor, the first sensor being arranged at an inlet of the cooling system of the server device, and the second sensor being arranged at an outlet of the cooling system; and
determine the first flow rate difference information of the cooling system according to a frequency of the first flow rate signal and a frequency of the second flow rate signal.

18. The device of claim 10, wherein the controller is further configured to:
in response to at least one of the outlet flow rate or the inlet flow rate of the cooling system being smaller than a fourth threshold, output the third status prompt information, the third status prompt information indicating that the cooling system has a blockage risk.
